(19) United States
(12) Patent Application Publication
(10) Pub. No.: US 2002/0024137 A1
(43) Pub. Date: Feb. 28, 2002

(54) Method of securing solder balls and any components fixed to one and the same side of a substrate

(76) Inventors: Lars-Anders Olofsson, Jarfalla (SE); Ivan Jonas, Akersberga (SE)

Correspondence Address: NIXON & VANDERHYE P.C., 8th Floor, 1100 North Glebe Road, Arlington, VA, 22201, US

(21) Appl. No.: 09/922,921

(22) Filed: Aug. 7, 2001

(30) Foreign Application Priority Data
Aug. 8, 2000 (SE) 0002850-6

(51) Int. Cl. H01L 23/48

(52) U.S. Cl. 257/738

(57) ABSTRACT

To transfer mold a transfer molding compound on a substrate having discrete components (2) and solder balls (3) on one and the same side, the discrete components (2) having a height that is less than the diameter of the solder balls (3), the substrate is placed on one part (6) of an transfer molding tool with the components (2) and the solder balls (3) facing the other part (7). When the parts (6, 7) of the transfer molding tool are pressed together, that other part (7) is adapted to receive the components (2) and the solder balls (3) and comprises flat-bottomed cavities (8) for individually receiving a top portion of each solder ball (3) and for flattening the top portion of each solder ball (3).

### TECHNICAL FIELD

The invention relates to safely securing solder balls and any discrete components fixed to one and the same side of substrates.

### BACKGROUND OF THE INVENTION

In operation, solder balls on ball grid array (BGA) modules as well as solder bumps on dies and on substrates in chip scale packages (CSPs) are all exposed to thermomechanical stress. So are also any discrete components mounted on the same side as the solder balls or solder bumps. Moreover, these discrete components will also be exposed to moisture, contamination, aggressive substances, compression, shocks etc.

After that e.g. a BGA module is mounted on a substrate by soldering the solder balls to bonding pads on the substrate, it is known to fill the gap between the BGA module and the substrate with an underfill material to protect the solder balls and any discrete components mounted on the same side of the BGA module as the solder balls.

Besides the fact that filling such gaps with an underfill material is time-consuming, and consequently expensive, such an underfill material can affect the electric properties of the discrete components on the BGA module since the dielectric constant is changed around these components.

### SUMMARY OF THE INVENTION

The object of the invention is to bring about protection of the solder balls and any discrete components mounted on the same side of a substrate as the solder balls and at the same time improve both the solderability of the solder balls and their reliability what concerns thermomechanical stress.

This is attained by covering the discrete components with a layer of a molding compound and by flattening the solder balls and surrounding them partly by that molding compound.

Hereby, a mechanically more stable unit as such is obtained at the same time as its solderability is improved.

### BRIEF DESCRIPTION OF THE DRAWING

The invention will be described more in detail below with reference to the appended drawing on which

FIG. 1 is a cross-sectional view of an embodiment of an transfer molding tool according to the invention in its open position with a BGA module to be transfer molded in accordance with the invention,

FIG. 2 illustrates the transfer molding tool of FIG. 1 in its closed position, and

FIG. 3 is a perspective view of an embodiment of a BGA module according to the invention.

### DESCRIPTION OF THE INVENTION

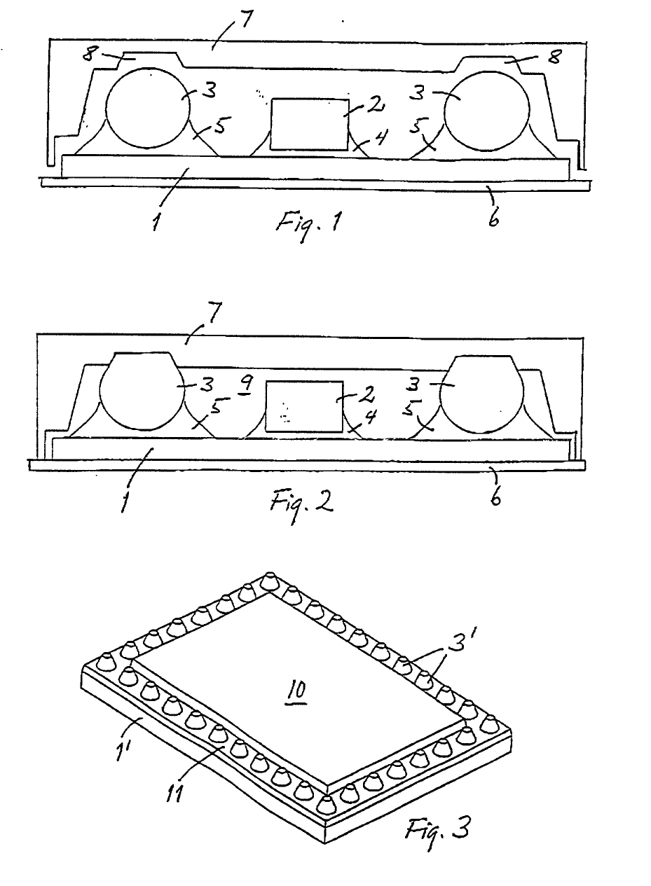

FIG. 1 is a cross-sectional view of a BGA module comprising a substrate 1 shown with only one discrete component 2 and two solder balls 3 fixed to the substrate 1 by means of e.g. solder joints 4 and 5, respectively.

It is to be understood that, normally, there are more than one discrete component fixed to the substrate 1 and a number of solder balls 3 alone all four edges of the substrate 1. However, it is to be understood that the invention is applicable also to the case when there are just solder balls and no discrete components fixed to the substrate.

The diameter of the solder balls 3 is larger than the height of any discrete component 2.

In FIG. 1, the substrate 1 with the component 2 and the solder balls 3 is located in an embodiment of an opened transfer molding tool according to the invention, comprising a lower stationary part 6, and an upper movable part 7 to be pressed towards to the stationary part 6.

It is to be understood that, equally well, the lower part can be movable and the upper part can be stationary.

In the embodiment in FIG. 1, the substrate 1 rests on the stationary part 6 with the component 2 and the solder balls 3 facing upwards towards the movable part 7.

In accordance with the invention, on its side facing the component 2 and the solder balls 3, the movable part 7 of the transfer molding tool is provided with a flat-bottomed cavity 8 for each solder ball 3. Each cavity 8 can have the shape of e.g. a truncated cone.

When the molding tool is compressed, i.e. the movable part 7 is pressed against the stationary part 6, each solder ball 3 is received in its corresponding cavity 8. By the compressing force exercised by the movable part 7, the top portion of the solder balls 3 fills out the respective cavity 8 to be formed accordingly, whereby the top portion of the solder balls 3 is flattened by the flat bottom of the cavities 8. Hereby, the solderability of the solder balls is improved.

It is to be understood that, equally well, the flat-bottomed cavities for receiving the solder balls can be provided on the lower part of the molding tool.

FIG. 2 illustrates the position in which the movable part 7 of the transfer molding tool is fully compressed with the stationary part 6. As apparent from FIG. 2, the top portion of the solder balls 3 fills out the respective cavity 8 and is flattened.

A gap 9 is formed between the stationary part 6 and the movable part 7 of the transfer molding tool. This gap 9 extends around the solder balls 3.

In accordance with the invention, a transfer molding compound, i.e. a thermosetting compound, is supplied to the gap 9 between the stationary part 6 and the movable part 7 of the transfer molding tool. This compound fills the gap 9 and forms a layer that covers the component 2 and surrounds the solder balls 3.

This layer of thermosetting compound will enable the substrate 1 with the component 2 and the solder balls 3 to better withstand thermomechanical stress. Also, the layer of thermosetting compound will make the substrate 1 with the component 2 and the solder balls 3 more robust. The flattened solder balls 3 will very much improve the solderability of the solder balls 3 of the BGA module to bonding pads on e.g. a printed circuit board.

Instead of transfer molding using a thermosetting compound, injection molding using a thermoplastic compound can be used.

It is to be understood that the height of the layer of molding thermosetting or thermoplastic compound does not have to be uniform throughout the gap 9 between the stationary part 6 and the movable part 7 of the transfer molding tool. Instead, the movable part 7 of the transfer molding tool can be designed such that the layer of thermosetting compound that surrounds the solder balls 3 will be lower than the layer of thermosetting compound that covers the components 2. Hereby, the performance of the solder balls what concerns thermomechanical stress improves even more.

FIG. 3 is a perspective view of such an embodiment of a BGA module. A substrate 1′ is provided with a number of cone-shaped solder balls 3′ along its edges. The not-shown components, if any, are covered by a layer 10 of thermosetting compound and the solder balls 3′ are surrounded by a layer 11 of thermosetting compound that is lower than the layer 10.

As should be apparent from the above, the semiconductor component or module according to the invention will better withstand thermomechanical stress and is more robust than similar components and module known so far. At the same time, the solderability of the component or module is improved.

1. A method of securing solder balls and any components fixed to one and the same side of a substrate, the components, if any, having a height that is less than the diameter of the solder balls, characterized by
placing the substrate in a compressible molding tool having flat-bottomed cavities for individually receiving a top portion of each solder ball,
compressing the molding tool to form the top portion of the solder balls received in said cavities to have a flat top, and
supplying a molding compound into the molding tool to mold said compound to cover any components and surround at least a part of each solder ball.

2. The method according to claim 1, characterized by forming the solder balls into truncated cones.

3. A semiconductor component comprising discrete components (2) and solder balls (3) fixed to one and the same side of the semiconductor component, characterized in that the solder balls (3) are formed to have a flattened top, and that a molding compound (10, 11) covers the discrete components (2) and surrounds the solder balls (3).

4. The component according to claim 3, characterized in that the solder balls (3) are formed into truncated cones (3′).

5. The component according to claim 3 or 4, characterized in that the molding compound (11) surrounding the solder balls (3′) is lower than the molding compound (10) covering any discrete components (2).

6. A molding tool comprising two parts (6, 7) to be pressed together for molding a molding compound on a substrate having discrete components (2) and solder balls (3) on one and the same side, the discrete components (2) having a height that is less than the diameter of the solder balls (3), characterized in that one part (6) is adapted to receive the substrate with the components (2) and the solder balls (3) facing the other part (7), and that said other part (7) comprises flat-bottomed cavities (8) for individually receiving a top portion of each solder ball (3) and for forming the top portion of each solder ball (3) to have a flat top when the parts (6, 7) are pressed together.

7. The tool according to claim 6, characterized in that the cavities (8) are cone shaped.
